(19) United States
(12) Patent Application Publication
(10) Pub. No.: US 2010/0022036 A1
(43) Pub. Date: Jan. 28, 2010

(54) METHOD FOR FORMING PATTERN, AND TEMPLATE

(76) Inventors: Ikuo YONEDA, Yokohama-shi (JP); Takumi Ota, Yokohama-shi (JP); Takeshi Koshiba, Yokohama-shi (JP)

Correspondence Address: FINNEGAN, HENDERSON, FARABOW,;GARRET & DUNNER L.L.P., 1300 I Street, N.W., Washington, DC, 20005-3315, US

(21) Appl. No.: 12/179,804

(22) Filed: Jul. 25, 2008

(51) Int. Cl. H01L 21/66

(52) U.S. Cl. 438/16; 257/E21.53

(57) ABSTRACT

According to an aspect of the present invention, there is provided a template including: a template substrate; patterns for forming device patterns on a wafer substrate; and a charging monitoring pattern, a size of the charging monitoring pattern being equal to a largest pattern in the patterns for forming the device patterns.

### BACKGROUND OF THE INVENTION

1. Field of the Invention

An aspect of the present invention relates to a method for forming pattern, and a template.

2. Description of the Related Art

As semiconductor integrated circuits are miniaturized and increased in integration density, photolithography apparatus as implementations of pattern transfer techniques for realizing fine patterning are required to be increased in precision. Such photolithography apparatus are thus associated a problem that the apparatus cost is increased.

In contrast, step and flash imprint lithography (SFIL) has been proposed as a technique for forming fine patterns at a low cost (refer to JP-2001-68411-A, for example). This is a method for transferring patterns to a resist layer in the following manner. A stamper (template) that has projection/recess patterns corresponding to patterns to be formed on a substrate is pressed against a liquid photo-curable organic material layer applied to a transfer subject substrate surface, and this state is maintained until the organic material is spread to conform to the projection/recess patterns. Then, the organic material layer is cured by illuminating it with light and the template is separated (removed) from the organic material layer.

If the holding time from the pressing of the template against the substrate surface to the light illumination is too short, the organic material is not sufficiently charged into the projection/recess patterns and the shape accuracy of transferred patterns becomes low. If such processing as etching is performed by using a resist having such patterns, problems will occur; for example, abnormal shapes are produced as a result of the processing.

Although the organic material comes to be charged into the projection/recess patterns so as to conform to them more completely as the holding time is increased, the throughput is lowered.

### SUMMARY OF THE INVENTION

An object of the present invention is to provide a method for forming pattern which can optimize the time for charging an organic material into a template, do not cause an organic material charging failure, and provide high throughput.

According to an aspect of the present invention, there is provided a template including: a template substrate; patterns for forming device patterns on a wafer substrate; and a charging monitoring pattern, a size of the charging monitoring pattern being equal to a largest pattern in the patterns for forming the device patterns.

According to another aspect of the present invention, there is provided a method for forming pattern by using of a template including: a template substrate; patterns for forming device patterns on a wafer substrate; and a charging monitoring pattern, a size of the charging monitoring pattern being equal to a largest pattern in the patterns for forming the device patterns, the method including: applying an organic material onto a surface of the wafer substrate; bringing the template into contact with the organic material; monitoring a charging status of the organic material into the charging monitoring pattern of the template; and illuminating the organic material through the template.

### BRIEF DESCRIPTION OF THE DRAWINGS

Embodiments may be described in detail with reference to the accompanying drawings, in which:

FIG. 1 shows the configuration of a pattern forming apparatus according to a first embodiment of the present invention;

FIG. 2 is a top view of a template;

FIG. 3 is a graph showing a relationship between the pattern size and the organic material charging time;

FIGS. 4A-4E are sectional views showing a method for forming pattern (process) according to the first embodiment;

FIG. 5 shows the configuration of a pattern forming apparatus according to a second embodiment of the present invention;

FIG. 6 is a top view of a template;

FIGS. 7A and 7B show an example charging detector;

FIG. 8 is a graph showing variations, over time, of the light detection intensity detected by the charging detector;

FIGS. 9A-9E are sectional views showing a method for forming pattern (process) according to the second embodiment;

FIG. 10 shows the configuration of a pattern forming apparatus according to a third embodiment of the present invention; and

FIG. 11 is a top view of a template.

### DETAILED DESCRIPTION OF THE INVENTION

Embodiments of the present invention will be hereinafter described with reference to the drawings.

### First Embodiment

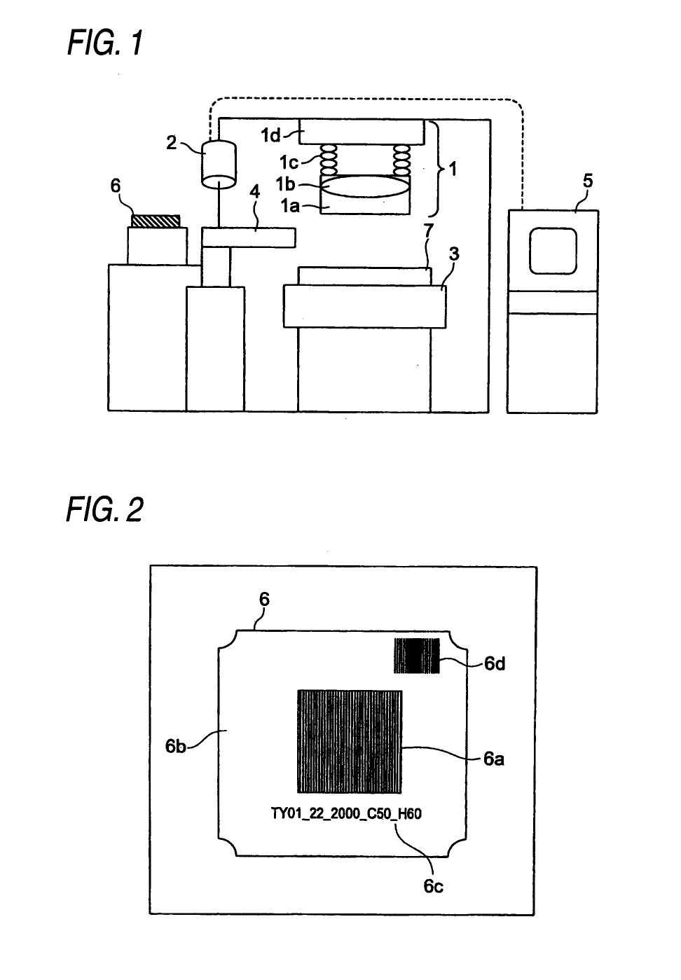

FIG. 1 shows the configuration of a pattern forming apparatus according to the first embodiment. The pattern forming apparatus is equipped with a light illumination unit 1, a barcode sensor 2, a wafer supporter 3 that holds a wafer 7, a template transport unit 4, and a control unit 5. The light illumination unit 1 is equipped with a chuck 1a, a lens 1b, an expansion/contraction member 1c, and a light source 1d.

The chuck 1a grips a template 6 that is transported by the template transport unit 4. Light emitted from the light source 1d passes through the lens 1b and shines on the template 6 being gripped by the chuck 1a.

FIG. 2 shows a top surface of the template 6. The template 6 has projection/recess patterns at a central portion 6a of one surface (wafer-side surface). The projection/recess patterns are formed to correspond to the patterns to be formed on the wafer 7. A template ID 6c and a barcode 6d are written on a peripheral portion 6b of the other surface (light-illumination-side surface) of the template 6.

The template ID 6c includes template information such as a template name, a maximum size and aminimum size of the patterns that are included in the template 6, a pattern density, and a groove depth (pattern height). The barcode 6d contains the template information. The template 6 is made of a material that transmits light emitted from the light source 1d, such as quartz glass.

The barcode sensor 2 reads the barcode 6d and outputs the read-out template information to the control unit 5.

The control unit 5 controls the expansion/contraction member 1c and the light source 1d. A photo-curable organic material is applied by an ink-jet apparatus (not shown) to the surface of the wafer 7 being held by the wafer supporter 3, and the template 6 is brought into contact with the photo-curable organic material as the expansion/contraction member 1c is expanded.

While the contact state is maintained for a prescribed time, the photo-curable organic material is charged into the projection/recess patterns of the template 6. Then, light is emitted from the light source 1d, whereby the photo-curable organic material is cured. After the photo-curable organic material has been cured, the template 6 is separated (removed) from the photo-curable organic material by contracting the expansion/contraction member 1c.

The control unit 5 stores template holding time information that was acquired in advance. The template holding time information indicates relationships between the individual items (the maximum pattern size etc.) of the template information and optimum times to charge the photo-curable organic material into the projection/recess patterns of the template 6.

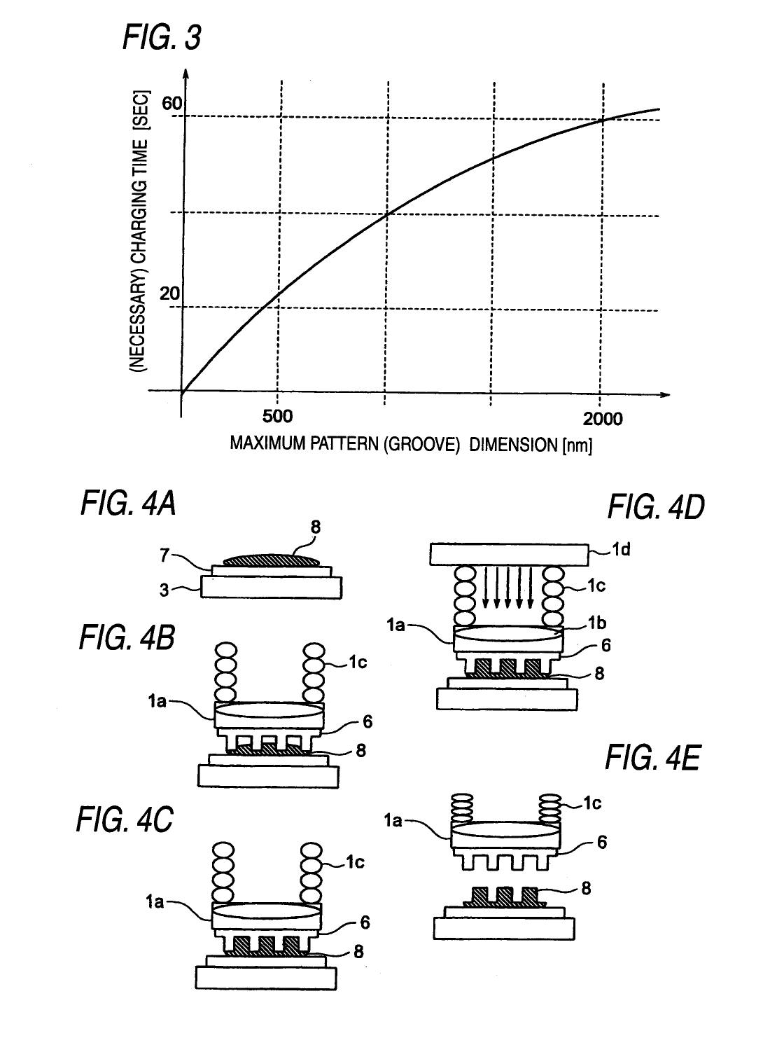

For example, as shown in FIG. 3, the charging time required to charge the photo-curable organic material increases as the maximum pattern (groove) size of the projection/recess patterns increases. The control unit 5 acquires and stores such information in advance as the template holding time information. Based on the template information that is read by the barcode sensor 2 and the template holding time information that is previously acquired, the control unit 5 calculates a holding time of the template 6, that is, a charging time of the photo-curable organic material into the projection/recess patterns.

For example, if the read-out template information includes information that the maximum pattern size is 1,000 nm, the holding (charging) time is calculated as 40 sec.

Upon a lapse of the holding time, the control unit 5 controls the light source 1d to emit light.

A process for forming patterns using the above pattern forming apparatus will be described below with reference to FIGS. 4A-4E, which are sectional views.

First, as show in FIG. 4A, a liquid photo-curable organic material 8 is applied to the surface of a wafer 7 being held by the wafer supporter 3 by means of the ink-jet apparatus (not shown). It is assumed that a template 6 whose template information has been read by the barcode sensor 2 is attached to the chuck 1a.

Then, as shown in FIG. 4B, the expansion/contraction member 1c is expanded and the template 6 being gripped by the chuck 1a is brought into contact with the photo-curable organic material 8 on the surface of the wafer 7.

Then, as shown in FIG. 4C, the contact state is maintained for a prescribed time, whereby the photo-curable organic material 8 is charged into the projection/recess patterns of the template 6. The holding time is calculated by the control unit 5 on the basis of the template information read by the barcode sensor 2 and holding time information stored in the control unit 5.

Subsequently, as shown in FIG. 4D, upon a lapse of the calculated holding time, light emitted from the light source 1d is applied to the photo-curable organic material 8 via the lens 1b and the template 6, whereby the photo-curable organic material 8 is cured.

Finally, as shown in FIG. 4E, the expansion and contraction member 1c is contracted and the template 6 is separated (removed) from the photo-curable organic material 8. Since the photo-curable organic material 8 is cured, it maintains the same state (shape) as in the state that the template 6 was in contact with it.

Since a template holding time (photo-curable organic material charging time) is determined on the basis of the shapes of the projection/recess patterns of the template 6, a failure in charging of the photo-curable organic material 8 can be prevented. Since the template holding time is set to an optimum time, throughput reduction can be prevented.

As described above, the pattern forming apparatus according to this embodiment can optimize the time for charging of an organic material into a template, prevent an organic material charging failure, and provide high throughput.

Although the above embodiment employs a relationship with the maximum pattern size as example template holding time information (see FIG. 3), a holding time may be calculated by using a relationship with the minimum pattern size, the pattern density, or the groove depth (pattern height) that was acquired in advance and is stored in the control unit 5.

### Second Embodiment

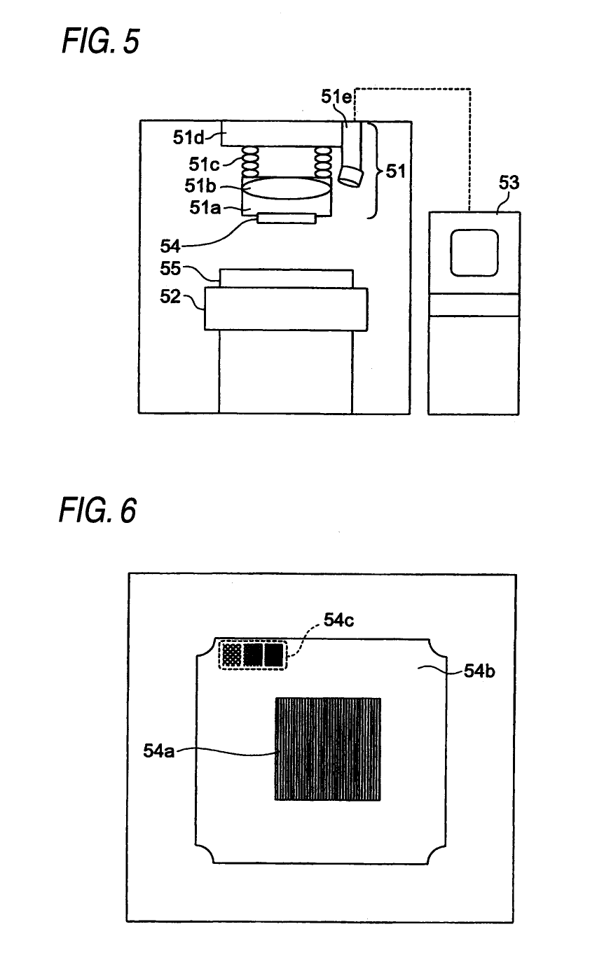

FIG. 5 shows the configuration of a pattern forming apparatus according to the second embodiment. The pattern forming apparatus is equipped with a light illumination unit 51, a wafer supporter 52 that holds a wafer 55, and a control unit 53. The light illumination unit 51 is equipped with a chuck 51a, a lens 51b, an expansion/contraction member 51c, a light source 51d, and a charging detector 51e.

The chuck 51a grips a template 54. Light emitted from the light source 51d passes through the lens 51b and shines on the template 54 being gripped by the chuck 51a.

FIG. 6 shows a top surface of the template 54. A central portion 54a of one surface (wafer-side surface) of the template 54 is projected and recessed in the same manner as patterns to be formed on the wafer 55. Furthermore, charging monitoring patterns 54c are formed in a peripheral portion 54b of the same surface (wafer-side surface) as the projection/recess patterns are formed of the template 54.

The charging monitoring patterns 54c are periodic patterns (e.g., lines and spaces or contact holes) of plural pattern sizes. The groove pattern size and the groove depth of the charging monitoring patterns 54c are set equal to a periodic pattern (e.g., lines and spaces or contact holes) included in the projection/recess patterns (main patterns) formed in the central portion 54a. For example, sets of lines and spaces or contact holes whose pattern widths are the same as a minimum pattern width and a maximum pattern width, respectively, of the main patterns are formed.

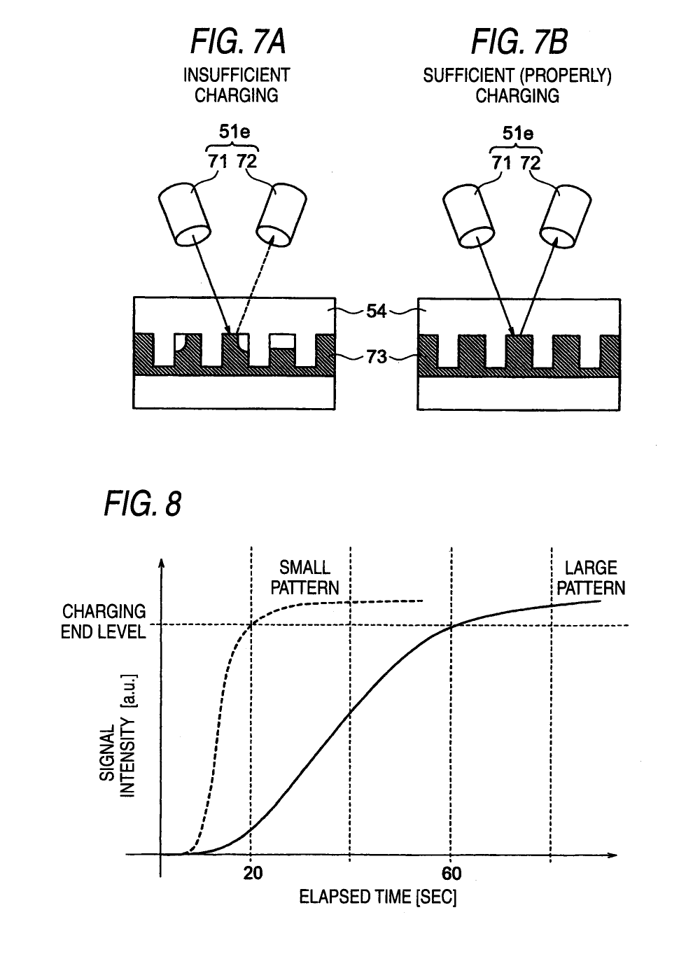

As shown in FIGS. 7A and 7B, the charging detector 51e is equipped with a light-emitting unit 71 and a light-receiving unit 72. Light emitted from the light-emitting unit 71 is reflected by a photo-curable organic material 73 in the charging monitoring patterns 54c of the template 54, and the light-receiving unit 72 receives reflection light. The light-emitting unit 71 emits light that has such a wavelength as not to cure the photo-curable organic material 73.

As shown in FIG. 7A, if the charging of the photo-curable organic material 73 in the charging monitoring patterns 54c of the template 54 is insufficient, the light detection level of the light-receiving unit 72 is low.

Conversely, as shown in FIG. 7B, if the charging of the photo-curable organic material 73 in the charging monitoring patterns 54c of the template 54 is sufficient, the light detection level of the light-receiving unit 72 is high because of a low degree of light scattering.

FIG. 8 shows example relationships between the elapsed time from contact of a template to a photo-curable organic material and the light detection level (signal intensity) detected by the light-receiving unit 72. FIG. 8 shows a case (solid line) of a charging monitoring pattern having a large size and a case (broken line) a charging monitoring pattern having a small size. It is seen that the signal intensity increases over time. A signal intensity saturation level is employed as a charging end level. A charging end level is acquired in advance and stored in the control unit 53 as charging end level information.

The control unit 53 controls the expansion/contraction member 51c, the light source 51d, and the charging detector 51e.

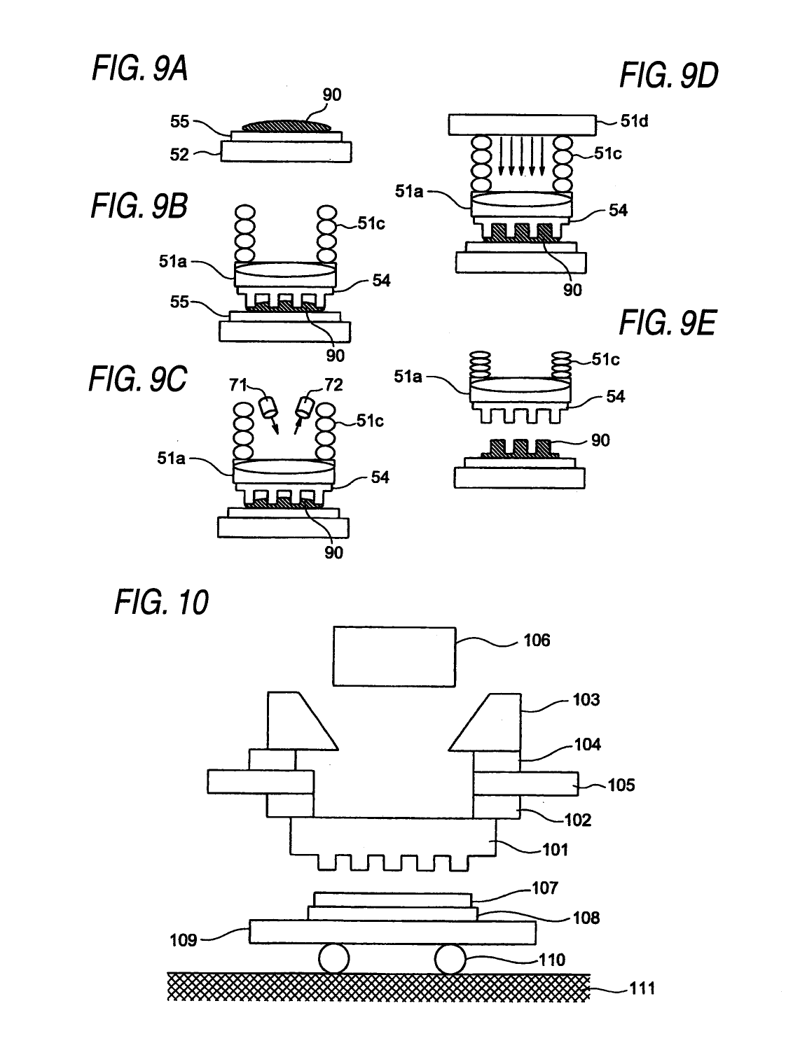

A process for forming patterns using the above pattern forming apparatus will be described below with reference to FIGS. 9A-9E, which are sectional views.

First, as show in FIG. 9A, a liquid photo-curable organic material 90 is applied to the surface of a wafer 55 being held by the wafer supporter 52 by means of an ink-jet apparatus (not shown).

Then, as shown in FIG. 9B, the expansion/contraction member 51c is expanded and a template 54 being gripped by the chuck 51a is brought into contact with the liquid photo-curable organic material 90 on the surface of the wafer 55.

Then, as shown in FIG. 9C, light emitted from the light-emitting unit 71 of the charging detector 51e is applied to the charging monitoring patterns 54c of the template 54. The light-receiving unit 72 detects reflection light and sends a light detection level to the control unit 53. The light that is applied to the charging monitoring patterns 54c has such a wavelength as not to cure the photo-curable organic material 90. The charging monitoring patterns 54c include plural patterns (e.g., lines and spaces or contact holes) having different pattern sizes, and light detection levels of reflection light beams from the respective patterns are sequentially detected and sent to the control unit 53.

Subsequently, if judging that the light detection levels of reflection light beams from the respective charging monitoring patterns 54c have reached the charging end level, the control unit 53 controls the light source 51d to emit light as shown in FIG. 9D. The light emitted from the light source 51d is applied to the photo-curable organic material 90 via the lens 51b and the template 54, whereby the photo-curable organic material 90 is cured.

Finally, as shown in FIG. 9E, the expansion/contraction member 51c is contracted and the template 54 is separated (removed) from the photo-curable organic material 90. Since the photo-curable organic material 90 is cured, it maintains the same state (shape) as in the state that the template 54 was in contact with it.

As described above, charging statuses of the charging monitoring patterns 54c that are formed according to the sizes of the projection/recess patterns of the template 54 are monitored and the photo-curable organic material 90 is cured by illuminating it with light after light detection levels detected by the light-receiving unit 72 have reached the charging end level. Therefore, a failure in charging the photo-curable organic material 90 into the projection/recess patterns of the template 54 can be prevented. Since the template 54 is held for an optimum time, throughput reduction can be prevented. Whether the organic material is properly charged in all patterns of the template depends on the charging status in the largest pattern of the template, as charging speed of the material into a larger pattern is slower than charging speed of the material into a smaller pattern. Then, in this embodiment, the size of the charging monitoring pattern is adjusted and is equal to the size of the largest pattern in the template patterns for device patterns. After the material is properly or fully charged in the charging monitoring pattern, illuminate the material through the template. Monitoring whether the material is properly or fully charged in the charging monitoring pattern is performed by causing a charging detector to illuminate the template with light that does not cure the organic material, receive reflection light and output detection light intensity, and by judging that the detection light intensity is higher than or equal to the prescribed level by the control unit.

As described above, the pattern forming apparatus according to this embodiment can optimize the time for charging of an organic material into a template, prevent an organic material charging failure, and provide high throughput.

Although in the above embodiment the charging monitoring patterns 54c are formed on the template 54, it is possible that no charging monitoring patterns 54c are formed and the charging detector 51e directly monitors a charging status of the projection/recess patterns in the central portion 54a of the template 54.

### Third Embodiment

FIG. 10 shows the configuration of a pattern forming apparatus according to the third embodiment. The pattern forming apparatus is equipped with an original plate holding stage 102 that holds a template 101, an alignment sensor 103, an alignment stage 104 to which the alignment sensor 103 is fixed, a base 105 to which the original plate holding stage 102 and the alignment stage 104 are fixed, a light source 106, a wafer chuck 108 that holds a wafer 107, a wafer stage 109 to which the wafer chuck 108 is fixed, a bearing 110, and stage surface plate 111.

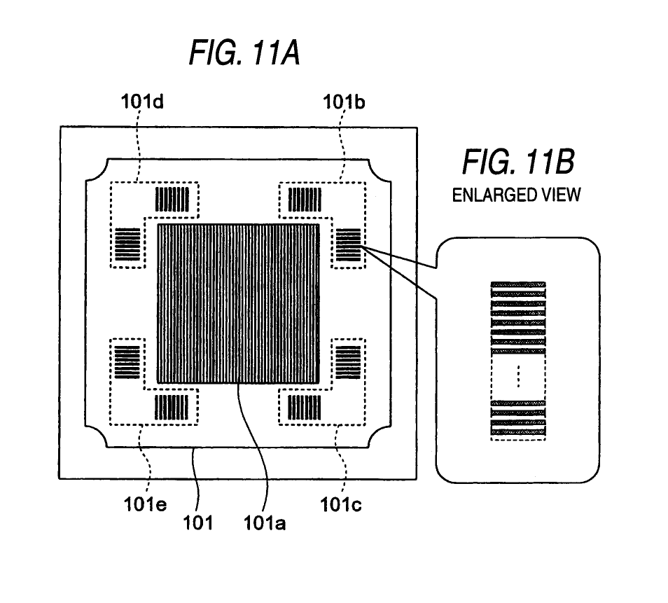

The light source 106 emits ultraviolet light. The template 101 is formed with projection/recess patterns (main patterns) that are the same as patterns to be formed on the wafer 107. The template 101 is made of a material that transmits ultraviolet light, such as quartz or fluorite. FIG. 11A shows a top surface of the template 101.

A central portion 101a of one surface (wafer-side surface) of the template 101 is projected and recessed in the same manner as patterns to be formed on the wafer 107. And alignment marks 101b-101e are formed at four positions, that is, at positions adjacent to the top-right corner, the bottom-right corner, the top-left corner, and the bottom-left corner of the central portion 101a of the template 101.

FIG. 11B is an enlarged view of part of the alignment mark 101b. Each of the alignment marks 101b-101e is two sets of lines and spaces that are equivalent to a design node of the main patterns. For example, each alignment mark has the same width as a minimum-width pattern included in the main patterns.

Although in this embodiment the alignment marks 101b-101e are formed at the four locations, satisfactory results are obtained as long as alignment marks are formed at three or more locations.

Having a drive axis for rotation around the Z-axis (θ), the original plate holding stage 102 positions the template 101. It is preferable that the original plate holding stage 102 further have drive axes for rotation around the X-axis (ωy) and the Y-axis (ωx). The original plate holding stage 102 also has positioning sensors (not shown) for measuring positions for the respective drive axes.

The base 105 is fixed by an apparatus body surface plate (not shown).

The alignment sensor 103 measures a relative positional deviation between the template 101 and the wafer 107 on the basis of the alignment marks 101b-101e formed on the template 101 and alignment marks drawn on the wafer 107 (i.e., alignment marks already formed in a lower layer). The measurement by the alignment sensor 103 is performed by using an optical inspection instrument or a scanning electron microscope (SEM), for example.

A positional deviation can be measured from an intensity distribution of light that is diffracted and reflected by the alignment marks and returns to the alignment sensor 103 when light is applied from the alignment sensor 103 to the alignment marks. The original plate holding stage 102 is moved so as to compensate for the measured positional deviation.

The wafer stage 109 can be moved via the bearing 110. It is preferable to drive the wafer stage 109 using six axes (X, Y, Z, ωx, ωy, and θ). The wafer stage 109 may be driven in the X and Y directions by linear motors in a state that it is floated over the stage surface plate 111 using compressed air or the like. The wafer stage 109 is equipped with positioning sensors (not shown) such as laser interferometers for measuring positions for the respective drive axes.

After the positional deviations of the template 101 have been compensated for, the template 101 is brought into contact with a liquid photo-curable organic material that is applied to the wafer 107. After the contact state has been maintained for a prescribed time so that the photo-curable organic material is spread to conform to the projection/recess patterns of the template 101, ultraviolet light is emitted from the light source 106 and applied to the back surface of the template 101. The photo-curable organic material is illuminated with the ultraviolet light through the template 101 and cured. After the photo-curable organic material has been cured, the template 101 is separated from it.

As a result, desired resist patterns are formed on the wafer 107. The patterns of the alignment marks 101b-101e are also transferred.

As shown in FIG. 3, the time taken to spread (charge) the photo-curable organic material so that it conforms to the projection/recess patterns of the template 101 increases as the pattern dimension increases. In general, alignment deviation inspection for alignment mark measurement is performed by using an optical inspection instrument. Therefore, the pattern size of an alignment mark is very large, that is, as large as several micrometers to tens of micrometers. As a result, the holding time for charging of an organic material is long and the throughput is low.

In this embodiment, since the alignment marks 101b-101e are lines and spaces that are equivalent to a design node of the projection/recess patterns in the central portion 101a of the template 101, the time taken to charge the photo-curable organic material into the projection/recess patterns can be made equal to the time taken to charge the photo-curable organic material into the alignment marks 101b-101e.

As described above, the pattern forming apparatus according to this embodiment can increase the throughput by setting a proper time for charging of a photo-curable organic material into a template.

The alignment marks 101b-101e employed in this embodiment may be formed in the template 6 or 54 used in the first or second embodiment. This optimizes the time for charging of the photo-curable organic material into the template 6 or 54 and thereby makes it possible to prevent a failure in charging the photo-curable organic material into the main patterns and the alignment marks 101b-101e and to increase the throughput.

The above-described embodiments are just examples and should not be construed restrictively. The technical scope of the invention is defined by the claims, and all changes that fall within meets and bounds of the claims or equivalence of such meets and bounds are therefore intended to be embraced by the claims.

What is claimed is:

1. A template comprising:
a template substrate;
patterns for forming device patterns on a wafer substrate; and
a charging monitoring pattern, a size of the charging monitoring pattern being equal to a largest pattern in the patterns for forming the device patterns.

2. A method for forming pattern by using of a template comprising: a template substrate; patterns for forming device patterns on a wafer substrate; and a charging monitoring pattern, a size of the charging monitoring pattern being equal to a largest pattern in the patterns for forming the device patterns, the method comprising:
applying an organic material onto a surface of the wafer substrate;
bringing the template into contact with the organic material;
monitoring a charging status of the organic material into the charging monitoring pattern of the template; and
illuminating the organic material through the template.

3. The method according to claim 2,
wherein the step of illuminating is performed after the material is fully charged into the charging monitoring pattern.

4. The method according to claim 2,
wherein the step of monitoring comprises:
illuminating the template with a monitoring light that does not cure the organic material;
receiving a reflection light of the monitoring light; and
judging whether a light intensity of the received reflection light is higher than or equal to a prescribed level.
